(19) United States
(12) Patent Application Publication
(10) Pub. No.: US 2003/0094666 A1
(43) Pub. Date: May 22, 2003

(54) Interposer

(75) Inventors: Gary Clayton, Boise, ID (US); Douglas G. Hastings, Meridian, ID (US)

Correspondence Address: ROBERT L. SHAVER, DYKAS, SHAVER & NIPPER, LLP, P.O. BOX 877, BOISE, ID, 83701-0877, US

(73) Assignee: R-TEC Corporation, Meridian, ID

(21) Appl. No.: 10/263,599

(22) Filed: Oct. 1, 2002

Related U.S. Application Data
(60) Provisional application No. 60/332,354, filed on Nov. 16, 2001.

(51) Int. Cl. H01L 31/00

(52) U.S. Cl. 257/459

(57) ABSTRACT

An improved interposer and method for making an interposer, for use in forming an electrical connection between electrical components. The interposer includes a bi-lobate contact pad made of an elastomeric material embedded with conductive metallic granules.

### PRIORITY

This application claims the priority date of the provisional application entitled Interposer filed by Gary Clayton and Douglas G. Hastings on Nov. 16, 2001, with serial No. 60/332,354.

### BACKGROUND OF THE INVENTION

1. Field of the Invention

The present invention generally relates to semiconductor and package testing, as well as electrical interconnections, and more particularly relates to a thin, flexible device for making electrical connections between two electrical components, called an interposer.

2. Background Information

There are a number of ways that one electrical component is attached to another electrical component. A chip being attached to a circuit board is one example. The goal of such a connection is to have good electrical conductivity, efficient assembly, and economical manufacture. This task has been accomplished in the past by probes being inserted into a socket, which may be soldered in place, or held by friction fit devices of various kinds. A problem with devices involving a protruding electrode is that under higher frequencies, the protruding electrode can act as a radio antennae, and energy losses due to radio frequency transmission and subsequent diffusion of the energy are detrimental to the circuit. Therefore, there is a need in the industry to build a device which securely connects electrical components, in a way that does not lead to loss of signal. One structure which has been utilized to accomplish this is a device called an interposer. An interposer is a thin, flat membrane that provides electrical connection between an electronic component above and below it. A number of interposer designs exist in the prior art.

The interposer shown in Prior Art “A” in FIG. 1 is also seen in a photograph enclosed. The darkened columns are formed of metallic granules embedded in an elastomeric matrix. The area between columns is also made of the elastomeric matrix in which there are few or no conductive particles. The particles are nickel-plated and are approximately 0.003 inches to 0.010 inches in size. The columns are approximately 0.5 mm in diameter. The distance between the columns is approximately one millimeter. Columns such as these may be formed in an clastomeric material by mixing conductive metal particles with a chosen elastomeric material. The particles are then formed into discrete columns by the use of very small electromagnets which attract the conductive particles into a concentrated column. They are held there until the elastomeric matrix is solidified enough to prevent them from dispersing again. When compressed, as shown in the figure to the right of Prior Art “A,” conductive pathways are formed by contact of the particles in the column.

There are several problems with this design. The conductive particles are large enough that when the column is compressed and an electric current is passed through the column, there may be only one or a few conductive pathways through the particles. It would be better if a large number of conductive pathways were formed through the column, or if the whole column became conductive. Another problem is that the columns can only be as small as the electromagnets can make them, and they can only be as tightly packed as the electromagnets can be packed. Currently, the pitch between the columns (the center to center spacing between the columns) and the diameter of the columns are not small enough to accommodate very small electrical components. Furthermore, if the particles are made smaller, the electromagnets would have that much less influence on each particle, and could not pack the columns as tightly. Therefore, there are some inherent limitations in this method of making conductive columns in an elastomeric material.

The prior art shown as Prior Art “B” in FIG. 1 is another type of interposer which utilizes an elastomeric material. In this interposer, metallic granules are dispersed randomly throughout the elastomeric material. The idea is that when the layer is compressed, several particles will contact each other, and form a conductive route from one side of the interposer to the other. The problem with this kind of interposer is that if the number of particles is increased in order to provide better conductivity, then there is increased leakage of the current to the sides of the compressed area. If there are not enough particles in this material, then the resistance is high because the route from edge to edge through the interposer layer is not sufficiently conductive.

Prior Art “C” in FIG. 1 is an interposer made by the author of the current patent, which utilizes hard copper contacts, which penetrate an insulative layer with columnar copper vias. This type of interposer forms an excellent contact, but has problems when the electrodes above or below the interposer present surfaces that are not perfectly coplanar. In such an instance, the insulative material can flex somewhat to allow adjacent contact pads to move up and down to compensate, but if the gap between one pair of electrodes is small and the gap between another pair of electrodes is wider, the second pair of electrodes may not have sufficient contact pressure to form a good, conductive connection.

Another type of prior art is made by forming a cylinder of elastomeric material filled with conductive metallic granules, which extend through a via in an insulative layer, such as that shown in Prior Art “D.” This contact pad design has the problem that it does not function very well with higher frequencies and it has high resistance. This conductive pad is formed by mechanically drilling a via through the insulating layer, and thus the diameter of the via is limited by the size of the mechanical drilling apparatus. The smallest hole that can be drilled in this manner is about 0.006 inches.

The interposer of Prior Arts “A,” “B,” and “D” are formed in a grid array and are not able to be formed in a customized format. Because of the manufacturing techniques used, the pitch between conductive pads is not sufficient to meet the needs of very small electrical components, or components with tightly packed electrodes.

Other problems of partially blocked electrical connectors occur when photoresist is incorrectly sized so that part of the electrode is covered on all sides of the electrode, leaving only a small hole in the center for contact. In those cases, an electrode with some compressibility needs to be pressed into the less than optimal opening for contact. When the distance between an array of pairs of electrodes is not uniform, a compressible interposer allows good contact when pressed between electrical components with differing gaps between the paired contacts.

What is needed is an interposer which has a very small pitch, or center-to-center distance between conductive pads. The interposer needs to have very good conductance from one side to the other, have very low resistance, and be able to handle high frequencies without leakage or other loss of signal. An improved interposer also needs to be able to be formed into customized and unique patterns in order to meet the connection requirements of a variety of specialized electrode patterns. It also needs to have a certain degree of compressibility, to accommodate issues of co-planarity. It also needs to have a profile and enough compressibility to cause the electrode to protrude into a partially blocked opening and mold itself into such an opening to create a good connection. Such a partially blocked opening can be formed when an opening in photoresist is not perfectly placed over the electrical connection, but instead partially obscures it.

### SUMMARY OF THE INVENTION

These and other objects are achieved by the approved interposer of the present invention. The interposer of the present invention is formed of an insulating layer on which a number of conductive pads are positioned. The conductive pads penetrate through a via in the insulating layer. The portion of the conductive pad that goes through the via is called a connecting column, and it has a first end and a second end.

On either end of the connecting column is a conductive region. On the first end of the connecting column is a first conductive region, and attached to the second end of the connecting column is a second conductive region. The connecting column passes through the via in the insulating layer, and the conductive pad is configured to conduct a current between the first conductive region, through the connecting column, and to the second conductive region. In one version of the invention, at least one of the conductive regions of the conductive pad is made of an elastomeric material in which a number of conductive metallic granules are embedded. The conductive region, which is made of elastomeric material, has a larger diameter than a cross section of the connecting column. This or any of the following configurations of the improved interposer may be made so that the conductive pads are configured to a specific pattern of electrodes of a chosen electrical component. The electrodes of an electrical component can be arranged in a grid array, or can have any number of specialized configurations, which can be matched by the configuration of the conductive pads of the improved interposer.

One configuration of the improved interposer has conductive pads that have a pitch of less than one millimeter. In other words, the center-to-center distance of the conductive pads is less than one millimeter, whether it be in an array, or in a specialized pattern of conductive pads set to match the pattern of a particular electronic component.

The improved interposer can also be made so that both of the conductive regions of the conductive pad, as well as the connecting column, are all made of elastomeric material, which is embedded with conductive metallic granules. One version of the improved interposer, as described above, utilizes conductive granules that have a diameter of less than 0.001 inches. The improved interposer described above can be configured to have a generally bi-lobate or dumbbell shape, with the first and second conductive regions having a larger diameter than the connecting column, with the connecting column passing through the insulating layer, and the larger sized conductive regions securing the conductive pad in place on the insulating layer. The cross-sectional shape of the via can be other shapes besides round, such as star shaped or with lobes, like those shown in the figures.

One version of the interposer of the invention can be composed of elastomeric material which is embedded with conductive metallic granules so that the conductive pad becomes conductive only when there is compression between the two sides of the device. That is, between the first conductive region, through the connecting column, and to the second conductive region. This occurs because as the elastomeric material is compressed, conductive metallic granules come into contact with each other, and one, and preferably more than one, route of conductivity is formed through the conductive metallic granules. If the conductive granules are densely packed, the entire column can be conductive, with light or no compression.

One version of the device is made of an elastomeric material embedded with conductive metallic granules, in which the conductive metallic granules make up approximately seventy to ninety percent, by volume, of the conductive pad. The device can also have an orienting feature that allows for the interposer to be positioned accurately in order to contact the chosen electrical components.

The invention also relates to a method of making an improved interposer. This method, in its broadest form, includes the steps of (1) providing a planar insulative layer with a first side and a second side; (2) using a laser to cut at least one via through the insulative layer; and (3) installing a conductive pad in the via, or vias, so formed, in which the conductive pad is made of an elastomeric material impregnated with conductive metallic granules.

The conductive pad which is thus installed, includes a first conductive region, a second conductive region, and a connecting column which connects the first and second conductive regions. The connecting column extends through one of the vias, and the first contact region is located on the first side of the planar insulating layer. The second contact region is located on the second side of the planar insulative layer.

The invention also includes a method of making an improved interposer which includes the following steps: (1) providing a planar sheet of insulative material with a first side and a second side; (2) covering the first and second sides of the planar sheet of insulating material with a stencil material in which the stencil material defines at least one first counter bore on the first side, and a corresponding second counter bore on the second side of the insulative material. These counter bores can be made in the stencil before it is applied to the insulative material, or after. The first counter bore and the second counter bore are arranged so that they are adjacent to each other, on opposite sides of the planar sheet of insulating material; (3) creating a via through the insulating material inside the first counter bore and the second counter bore. Typically, there would be more than one via and more than one pair of first and second counter bores. This method could include creating an array with many pairs of first counter bores and second counter bores, and vias penetrating through the insulative material; (4) filling the first counter bore via and the second counter bore via up to the top of the surface of the stencil with an elastomeric material containing conductive metallic granules; (5) removing the stencil material from the first side and the second side of the insulative layer, thus leaving in place conductive pads which are formed by the elastomeric material containing conductive metallic granules that fill the first counter bore, the conductive column, and the second counter bore.

The stencil material used in this method can be removed in several different ways. A laser can be used to remove the stencil. To remove the stencil using a laser, the laser is used to cut a number of perforations, or partial perforations, which allow the stencil to be physically broken into pieces and pulled off of the conductive pads. The stencil can also be removable by chemical means. If the stencil is water soluble, the stencil may be removed by the application of water. This would leave in place the conductive pads, which penetrate through the via of the insulative material.

In another version of the device, the stencil material is made of photoresist, and the first and second counter bores are made in the photoresist after it has been applied to both sides of the insulative material. The first and second counter bores are made in the stencil by selectively removing photoresist material from the stencil on the first and second sides of the insulating material. The first and second counter bores can be formed by chemical dissolution of the photoresist. The first and second counter bores may also be formed by the removal of stencil material by the use of a laser, and the via may also be drilled by using a laser. The stencil itself, when made of photoresist, may be removed by use of a chemical solvent.

The stencil may be a sheet of plastic that is placed adjacent to the insulating material, until the conductive pads are formed and cured. Then, it may be removed from the insulating material. The stencil material may also be formed of a flexible sheet held in place by an adhesive back, in which the flexible sheet contains a number of perforations. Each perforation would form a counter bore. Through vias in the insulating layer within each counter bore that could be drilled with a laser, and the counter bores and via filled with elastomeric material impregnated with conductive metallic granules. After the conductive pads thus formed were cured, this type of stencil would be removed by peeling it off, or chemically dissolving it.

Still other objects and advantages of the present invention will become readily apparent to those skilled in this art from the following detailed description wherein I have shown and described only the preferred embodiment of the invention, simply by way of illustration of the best mode contemplated by carrying out my invention. As will be realized, the invention is capable of modification in various obvious respects all without departing from the invention. Accordingly, the drawings and description of the preferred embodiment regarded as illustrative in nature, and not as restrictive.

### BRIEF DESCRIPTION OF THE DRAWINGS

FIG. 1 Prior Art “A,” “B,” “C,” and “D” are prior art examples of interposers.

FIGS. 2A and 2B drawings of prior art interposers.

FIG. 3A is a photograph showing a cross section of the interposer of the invention.

FIG. 3B is a top view of one conductive pad of the invention.

FIG. 3C is a photograph of an interposer of the invention that contains multiple conductive pads.

FIG. 3D shows an example of the circuitry with which the interposer of the invention is designed to interface.

FIG. 3E is a photograph of an interposer of the invention that contains a number of conductive pads.

FIG. 4 is a cross-sectional view of the interposer of the invention.

FIG. 5 is a perspective view of the interposer of the current invention with multiple conductive pads.

FIG. 6A shows a method of making the interposer of the invention in which a laser is used to drill a via.

FIG. 6B is a side view of an interposer of the invention which fills the via cut shown in FIG. 6A.

FIG. 7A shows the beginning step for making the interposer by one particular method.

FIG. 7B is a cross-sectional view showing the making of the interposer as a via is cut, and a first and second counter bore are cut.

FIG. 7C is a cross-sectional view showing the via and counter bores filled with conductive material.

FIG. 7D is cross-sectional view showing the interposer in position, and the stencil material removed.

FIG. 8 shows the stencil material being perforated by the use of a laser.

FIG. 9A shows the starting material for another method of making the interposer.

FIG. 9B shows the second step in this process of making an interposer, in cross-sectional view.

FIG. 9C shows a step in the process of making the interposer, in which a laser is used to cut a via.

FIG. 9D is a cross-sectional view of conductive elastomeric material placed in the via flush with the stencil layers.

FIG. 9E is a cross-sectional view with the stencil layers removed.

FIG. 10A is a cross-sectional view of the starting material for a process of making the interposer.

FIG. 10B is a cross-sectional view of the starting material with the stencil layers added.

FIG. 10C is a cross-sectional view showing the cutting of the via and counter bore areas with layers.

FIG. 10D shows a method of applying the elastomeric material by a pushing action.

FIG. 10E is a side view showing the application of elastomeric material using a roller action.

FIG. 11 is a process flow diagram for one method of making the invention.

FIG. 12 is a flow diagram showing additional information about the process of making the interposer.

FIG. 13 is a diagram that shows problems that an interposer is required to handle.

FIG. 14 shows an alternative embodiment of the interposer of the invention.

FIG. 15A is a cross-sectional view of the first step of making the interposer of FIG. 14.

FIG. 15B is a cross-sectional view of the next step of making an alternative embodiment of the interposer, in which stencil material is added to the layer of elastomeric material.

FIG. 15C is a cross-sectional view showing the cutting of the via and counter bores with a laser.

FIG. 15D is a cross-sectional view of the next step in the process of making the interposer of FIG. 14, in which elastomeric material is added to fill the via and counter bores.

FIG. 15E is a cross-sectional view of the next step of the process of making the interposer of FIG. 14, in which the stencil layers are removed.

### DESCRIPTION OF THE PREFERRED EMBODIMENTS

While the invention is susceptible of various modifications and alternative constructions, certain illustrated embodiments thereof have been shown in the drawings and will be described below in detail. It should be understood, however, that there is no intention to limit the invention to the specific forms or processes disclosed, but, on the contrary, the invention is to cover all modifications, alternative constructions, and equivalents falling within the spirit and scope of the invention as defined in the claims.

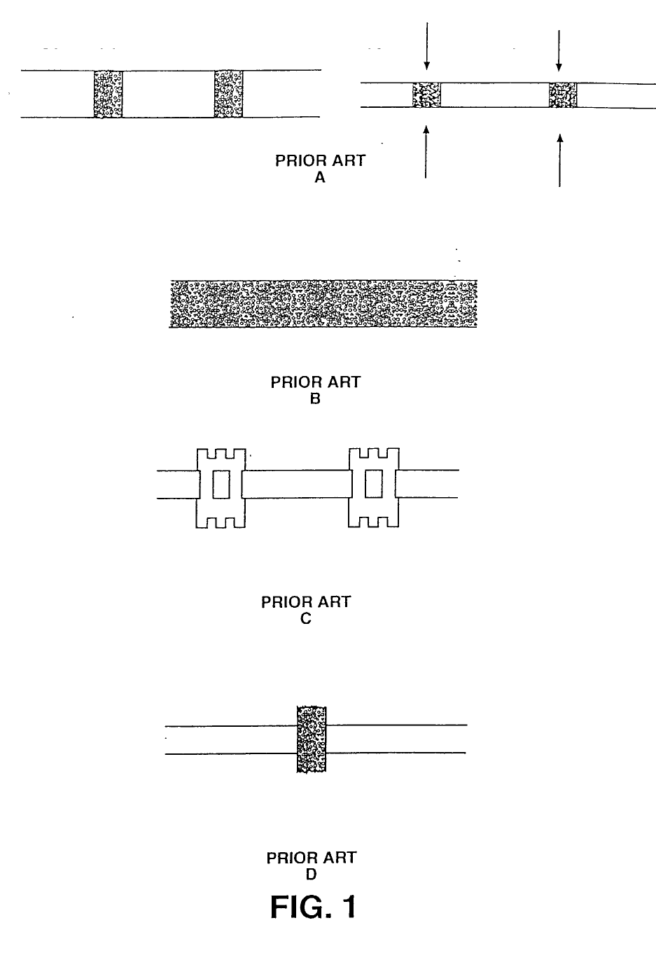

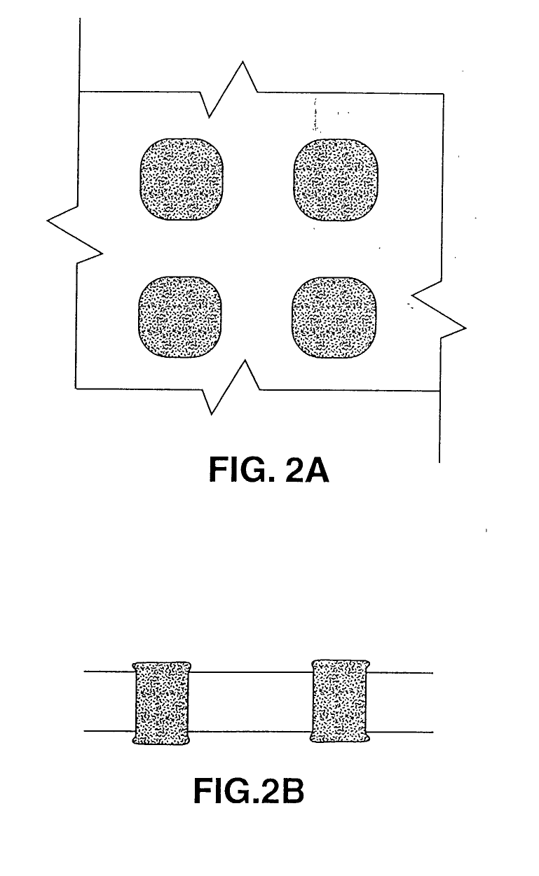

Several embodiments of the improved interposer are shown in the accompanying drawings. Also included in the drawings are descriptions of several methods of making the improved interposer. The problem with the prior art interposers as shown in FIGS. 1A though 1D, are solved by the interposer of the current design, which results in an interposer with elastomeric contacts, which are also sufficiently conductive that many conductive pathways are created from one side of the interposer to the other when contact is made with electrical components. This improved conductivity is achieved by a much smaller particle size of the conductive metallic granules than what is used in the prior art interposers. Not only are the granules much smaller, but they are much more concentrated, and yet sufficiently flexible that they can be compressed between the electrodes of electronic components. Although compression results in improved conductivity, the conductive pads of the interposer are conductive without compression. FIGS. 2A and 2B show prior art interposers as described above.

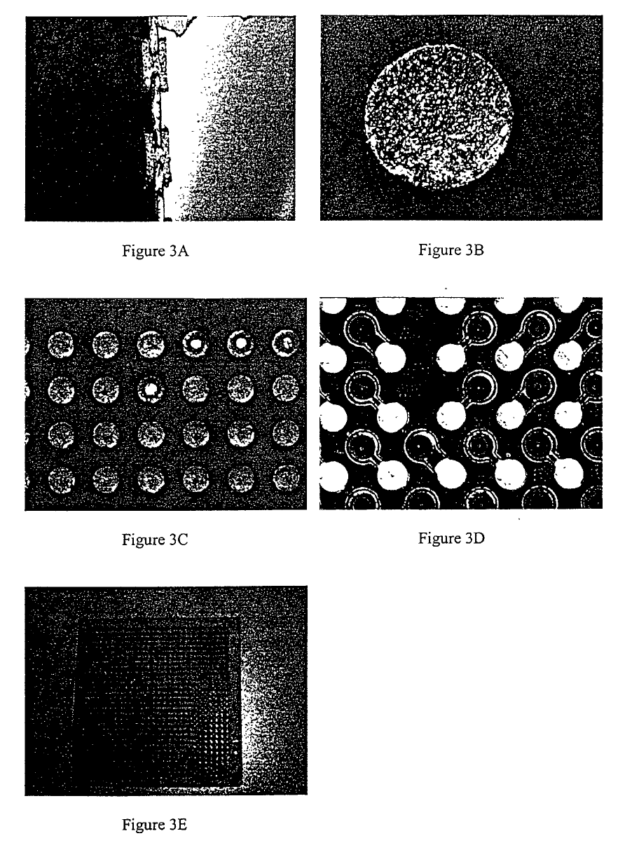

The compositional difference between the interposer of the invention and prior art interposers is also seen when comparing FIGS. 2A and 2B, and FIGS. 3A-3E. FIGS. 2A and 2B show conductive elastomers and interposers of prior art with entrapped metallic granules. FIGS. 2A and 2B show columns made of conductive metal granules entrapped in a sheet of elastomeric material. These columns are formed by magnetic attraction of the particles to electromagnets. By contrast, the conductive pads of the present invention are shown in the photographs of FIGS. 3A-3E. In FIG. 3A, two conductive pads are shown in cross section. In FIG. 3B, one conductive pad is shown. This conductive pad is smaller in diameter than the conductive pads of prior art interposers 2A and 2B, and the difference in size of the conductive metal granules can be seen in FIG. 3B. In FIGS. 3C and 3E shown is an interposer that contains a number of conductive pads. The pitch between the conductive pads of the present invention are much smaller than the pitch possible to achieve in the process used to make the prior art interposer shown in FIGS. 2A and 2B. The diameter of each conductive pad is also much smaller.

FIG. 3D is an example of the circuitry with which the interposer of the invention is designed to interface.

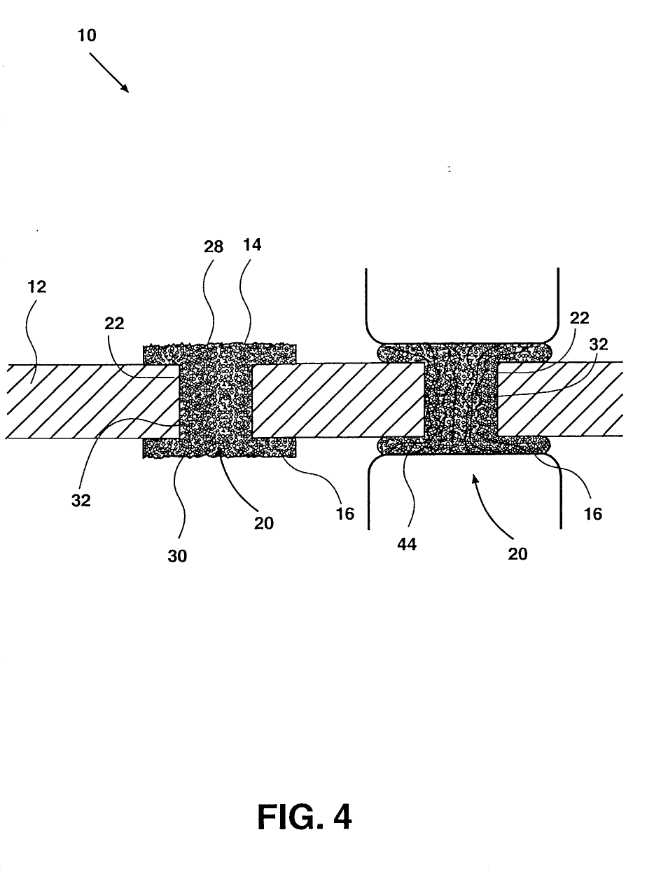

One preferred embodiment of the present invention is shown in FIGS. 3A, 3B, 3C, 3E, and FIG. 4. The embodiment shown in FIG. 4 of the invention shows two conductive pads 20, each with a first conductive region 28 and a second conductive region 30. The conductive pad 20 is comprised of elastomeric material, which includes small particles of conductive metal granules. The granules can be of any composition which is sufficiently conductive, including copper that is coated with nickel and silver or gold, or an aluminum which is coated with nickel, silver or gold. Other combinations are also possible, as long as the chosen material is sufficiently conductive.

The particles of the preferred embodiment are smaller than 0.001 inches in diameter. It has been found that granules of this size form a good conductive column if they comprise from 70% to 90% of the conductive pad 20, with about 75% by volume being an optimum composition. The composition of the conductive pad can include any number of elastomeric materials, which are impregnated with conductive granules of the appropriate size.

The insulative layer 12 shown in FIG. 4 can be formed of a number of insulating materials, but Kapton or FR4 is one product that has proven suitable for this application. As shown in FIG. 4, the elastomeric material 14 of the conductive pad 20 includes conductive metallic granules 16. These conductive metallic granules are so dense that multiple conductive routes 44 are formed through the conductive pad 20 when electrical components contact the conductive pad 20 at the first conductive region 28 and the second conductive region 30. The first conductive region 28 and the second conductive region 30 of the conductive pad 20 are larger in diameter than the diameter of the connecting column 32. Connecting column 32 passes through a via 22 formed in the insulating layer 12. The via 22, and consequently the connecting column 32 can be formed in a number of different cross sectional shapes, including circular, star-shaped, lobed, and other shapes. These varied cross-sectional shapes allow the designer of the interposer the flexibility to select a via shape which is small enough to secure the interposer in place, yet which contains enough conductive elastomeric material so that multiple conductive routes for electricity are provided through the connecting column 32.

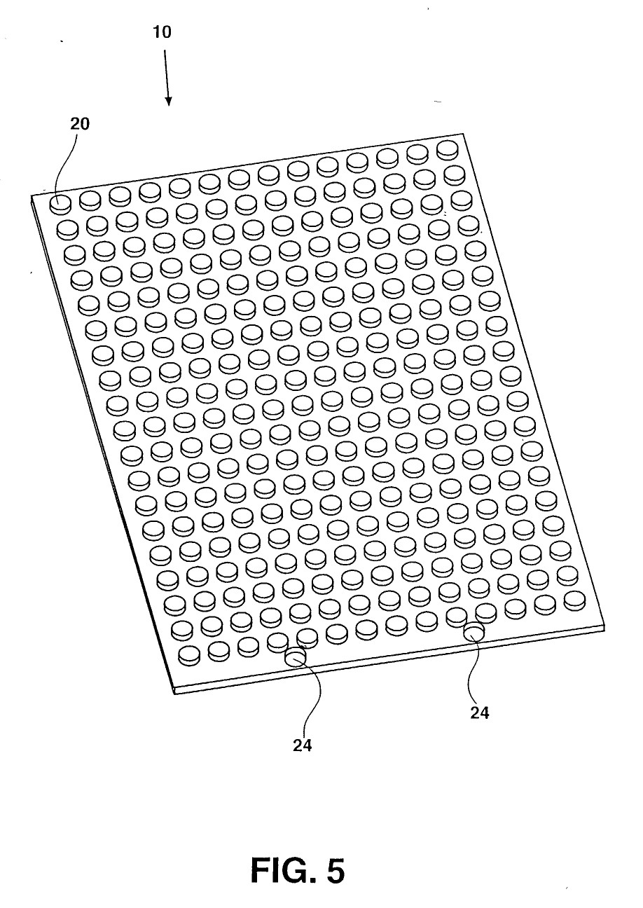

FIG. 5 shows an interposer 10 of the invention which includes an array of conductive pads 20. An interposer of the invention can be constructed with such an array, or with a uniquely configured pattern of conductive pads, including utilizing only one conductive pad. The interposer can be designed so that it has a unique footprint to match a particular electronic component. The interposer 10 of FIG. 5 also has two orienting features 24. These or some other type of orienting feature allows the improved interposer 10 to be positioned so that it matches perfectly with the footprint of a particular electronic component.

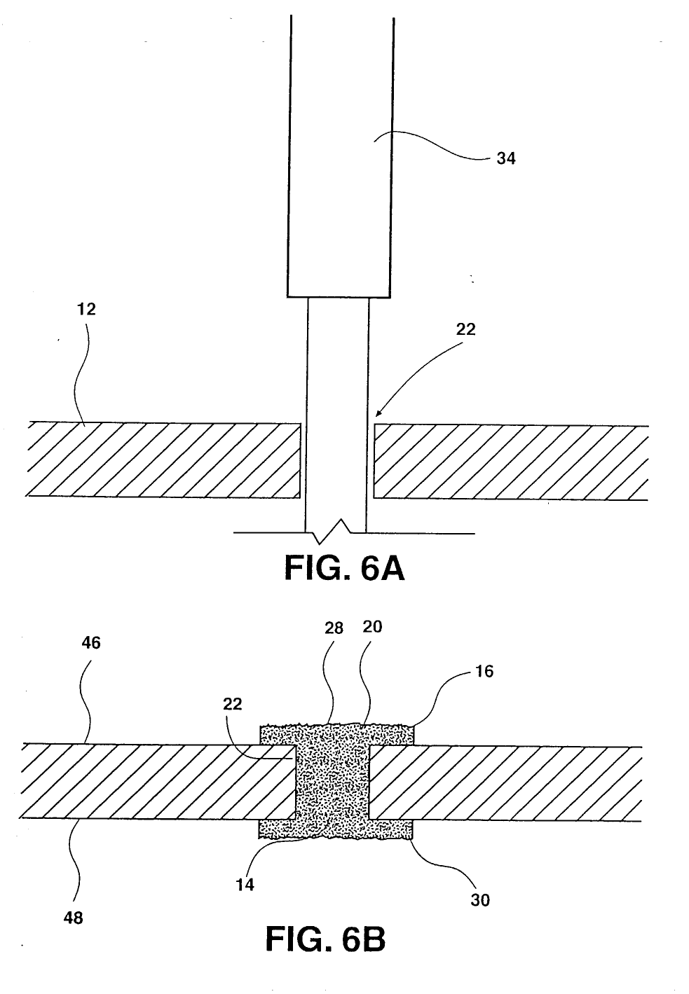

The invention also includes a method of making an improved interposer. One preferred method of making the interposer is shown in FIGS. 6A and 6B. This method includes the step of providing a planar insulative layer 12 as shown in FIG. 6A. A laser 34 is used to cut at least one via through the insulative layer. Typically, the interposer 10 would be constructed to include many conductive pads 20, although only one is possible, and only one is shown in FIGS. 6A and 6B. The next step in the method involves installing a conductive pad in the via. In the typical configuration, however, many vias 22 would be cut and one conductive pad 20 would be installed in each one. Each conductive pad 20 so installed includes a first conductive region 28, a second conductive 30, and a connecting column 32, with the connecting column 32 joining first conductive region 28 and second conductive region 30. The conductive pad 20 is made of elastomeric material 14 which includes conductive metallic granules 16. The planar insulating layer has a first side 46 and a second side 48. The first conductive region 28 is on the first side 46 of the insulating layer 12. The second conductive region 30 is on the second side 38 of the insulating layer 12. The diameter of the first and second conductive regions 28 and 30 is larger than the diameter of the connecting column 32.

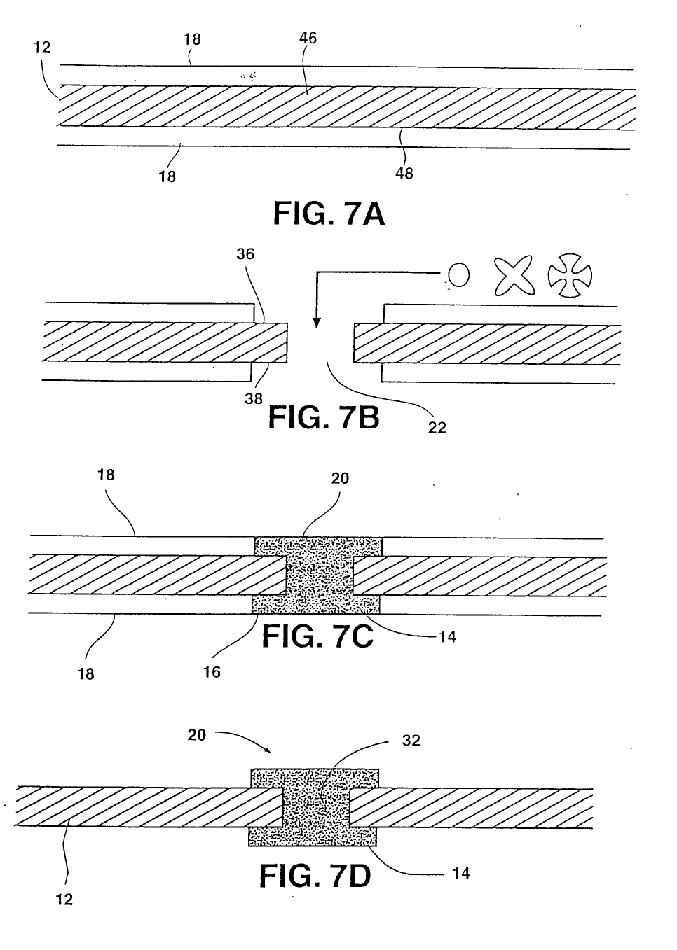

FIGS. 7A-7D show another preferred method of making the improved interposer. The method involves providing a planar sheet of insulating material 12 as shown at FIG. 7A. The planar sheet of insulating material 12 has a first side 46 and a second side 48. The next step involves covering the first side 46 and the second side 48 of the planar sheet of insulating material with a stencil material 18. Defined within the stencil material 18 is a first counter bore 36 and second counter bore 38. The next step of the process, shown at FIG. 7B, involves creating a via 22 through the insulating material 12, inside the first counter bore 36 and the corresponding second counter bore 38. The next step, at FIG. 7C, involves filling the first counter bore 36, the via 22, and the second counter bore 38 with an elastomeric material 14 containing conductive granules 16. The next step, FIG. 7D, involves removing the stencil material 18 as shown from the first side 46 and the second side 48 of the insulative layer 12. What remains is the insulative material 12 with at least one, and typically many more than one conductive pad 20.

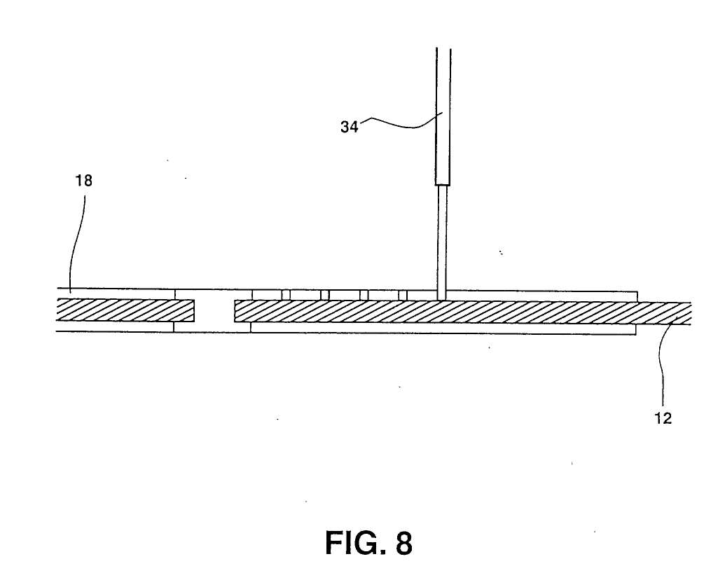

The last step of the method described above involves removing the stencil material from the insulative layer. This can be achieved in several ways. A laser can be utilized to remove the stencil material. Use of a laser to remove stencil material is shown in FIG. 8. In FIG. 8, a laser 34 is shown cutting a series of perforations 50 in the stencil material 18. After perforations 50 are cut in an appropriate pattern, the stencil material can be physically broken apart and removed from the insulating layer 12. The stencil material can also be removable by chemical means. If the stencil is a material which is water soluble, it can be removed by the application of water and the dissolution of the stencil material.

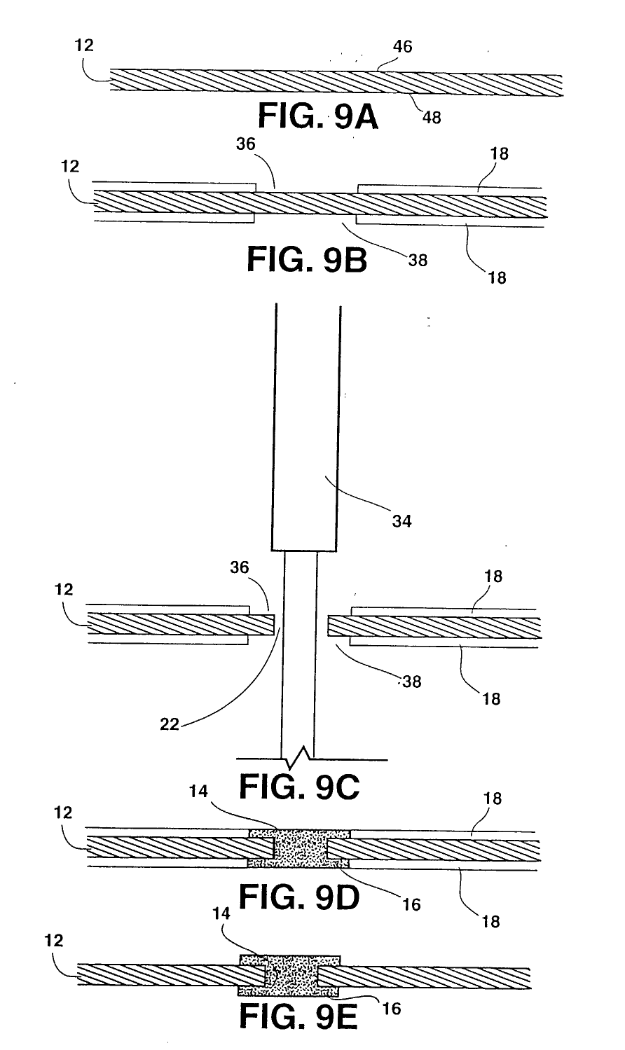

FIGS. 9A-9E show a method of making the interposer of the invention in which stencil layers 18 are applied to the insulative layer 12. Stencil layers 18 have first counter bore 36 and second counter bore 38, which can either be cut before or after applying the stencil 18 to the insulative layers. A laser 34 is shown cutting a via 22 inside the counter bores. Elastomeric material 14 fills the counter bores and via in FIG. 9D. The stencil layers 18 are removed in FIG. 9E, leaving the conductive pad 20 in the insulative layer 12.

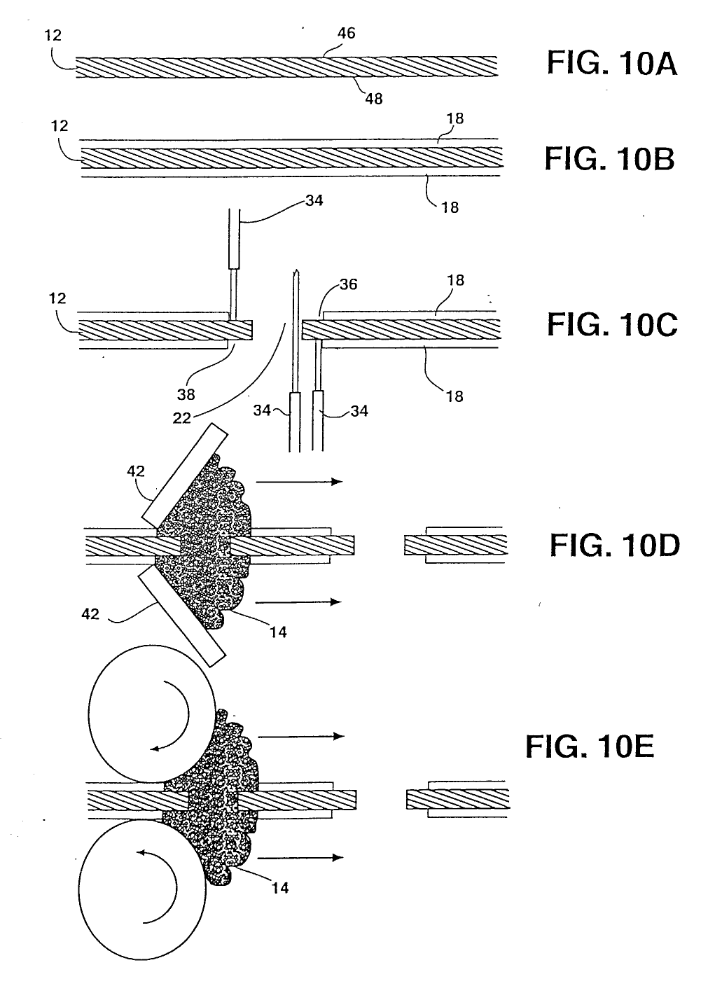

FIGS. 10A-10E show another preferred embodiment of the method of making the improved interposer of the invention. FIGS. 10A and 10B show stencil layers 18 being added to the insulative layer 12. At FIG. 10C, lasers 34 cut the counter bores 36 and 38, and via 22. FIG. 10D shows a spreader 42 pressing the elastomeric material 14 into the first counter bore 36, second counter bore 38, and via 22. FIG. 10E shows a pair of rollers performing this function. After thus filling the counter bores and via, the stencil layers are removed as discussed previously.

The preferred method of cutting the counter bores is by using a laser to cut through a layer of photoresist which acts as the template on the insulating layer. The setting of the laser to drill the counter bore in the via varies depending on the thickness of the insulating material and the thickness and type of photoresist or other template. One setting which works on a standard layer of photoresist is to use an ESI laser, set at 0.7 watts power, the velocity of 100, using 20 kHz. The counter bore is best cut using a spiral pattern which begins at the center and spirals outward to the outer edge. A preferred method of cutting the via in FR4 insulating material is to use an ESI laser, set at 1.2 watts, with a velocity of 7, and at 15 kHz, and the via is cut in a two step process. In the first step, the laser ablates a hole through the insulating material 12. In the second step, the laser is reconfigured to make a trepane cut at 1.2 watts, 60 velocity, and 15 kHz for three reps. In this second cut, the laser steps down 0.2 mm and trims the edges of the via.

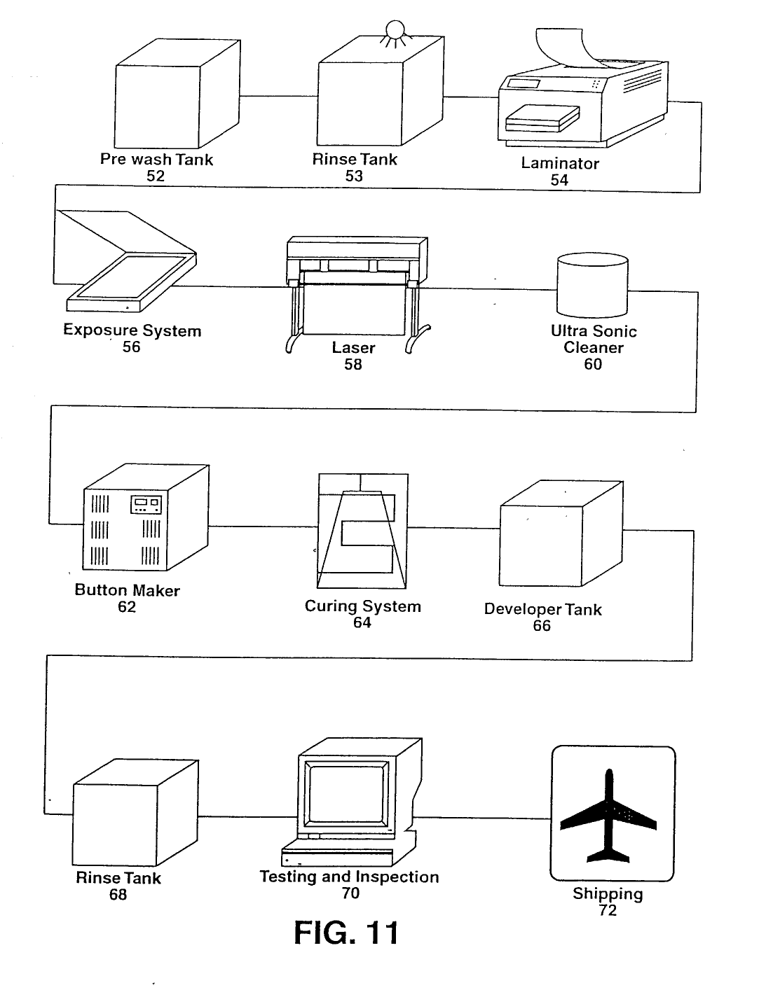

FIG. 11 shows the process flow in one preferred embodiment of the method of making the improved interposer of the invention. In FIG. 11, at block 52, is a prewash tank to clean the insulating material. At block 53, the insulating material is rinsed with deionized water. At block 54, the photoresist is laminated on both sides of the insulating material. At block 56, the photoresist is exposed by direct UV light. At block 58, the vias and counter bores are cut in the laminate.

At block 60, the laminate is cleaned of slag from the laser process. At block 62, the elastomeric material with conductive partials is placed in the vias and counter bores. At block 64, the elastomeric material is cured at room temperature at an elevated temperature or humidity cure, depending on the material used. At block 66, in the developer tank, the photoresist is removed. At block 68, the interposer is rinsed in deionized water to remove any residual developer. At block 70, the interposer is tested and inspected. At block 72, the interposer is shipped to the customer.

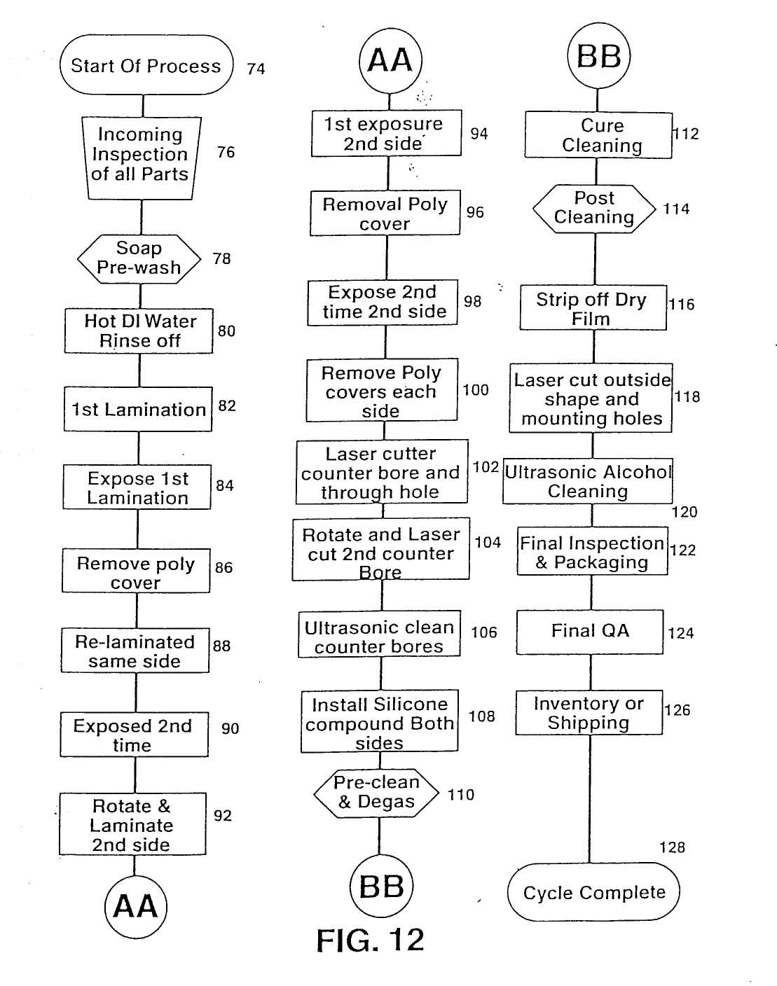

FIG. 12 is a more detailed description of one preferred embodiment of making the improved interposer. The process shown in FIG. 12 starts at step 74. At step 76, incoming parts are inspected for quality control parameters. At step 78, the insulative material is prewashed in soap. At block 80, the insulating material is rinsed in hot (180° F.) deionized water. At step 82, a stencil is applied in the form of a layer of photoresist. At block 84, the photoresist is exposed by UV light. At block 86, the protective poly cover is removed. At block 88, a stencil is applied in the form of a second layer of photoresist. At block 90, the second layer of photoresist is exposed by UV light. At block 92, the second side of the insulating material is laminated by applying a stencil in the form of a layer of photoresist. At block 94, the photoresist is exposed by UV light. At block 96, the protective poly cover is removed. At block 98, a stencil is applied in the form of a second layer of photoresist and the second layer of photoresist is exposed by UV light. At block 100, the protective poly cover is removed from both sides. At block 102, the laser ablates the material to create the vias and counter bores on the on side. At block 104, the laser ablates the material to create the counter bores on the second side. At block 106, the laminate is cleaned to remove any slag from the laser process. At block 108, elastomeric material with conductive particles is inserted into the vias and counter bores. At block 110, the elastomeric material is degassed. At block 112, the elastomeric material is cured with a room temperature cure, elevated temperature cure, or a humidity cure depending on the elastomeric material used. At block 114, cleaning of thereof the interposer to remove any elastomeric particles that are not adhered to the buttons. At block 116, the stencil or photoresist is removed. At block 118, the outside shape and alignment hole of the interposer is cut in the interposer. At block 120, a final clean with alcohol is performed. At block 122, the final inspection and packaging of the interposer is conducted. At block 124, final quality assurance to insure the pattern and the alignment feature are to engineering prints. At block 126, the interposer is put into inventory or shipped to the customer. At block 128, the cycle is complete.

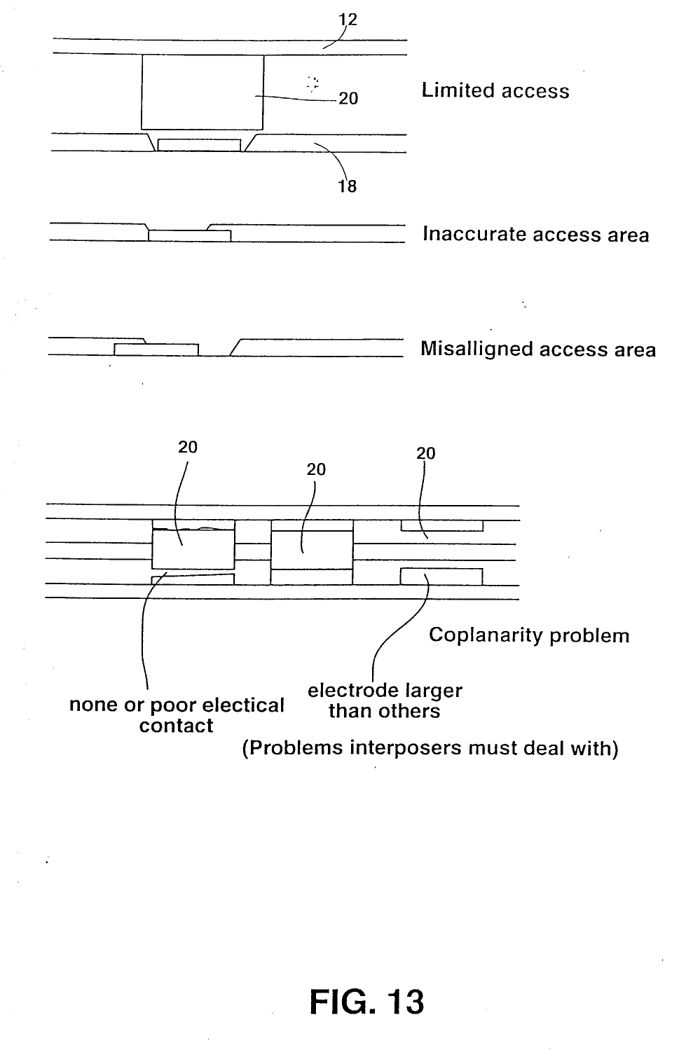

FIG. 13 shows some problems that are encountered by an interposer in trying to connect with electrical circuitry. The top illustration shows that there are situations in which access to the electrical contact is limited. In the case shown for limited access, the interposer 20 is larger in diameter than the area around the contact. In this situation, contact is made difficult. The next two examples in FIG. 13 show that during the process of manufacturing the electronic circuitry, the contact can be misplaced in relation to the surrounding material, making either an inaccurate access area, or a misaligned access area as shown. A fourth problem that interposers encounter is that the electrodes with which they interface can be of different thickness. The thicker electrodes will result in poor contact with the thinner electrodes. This is called a co-planarity problem.

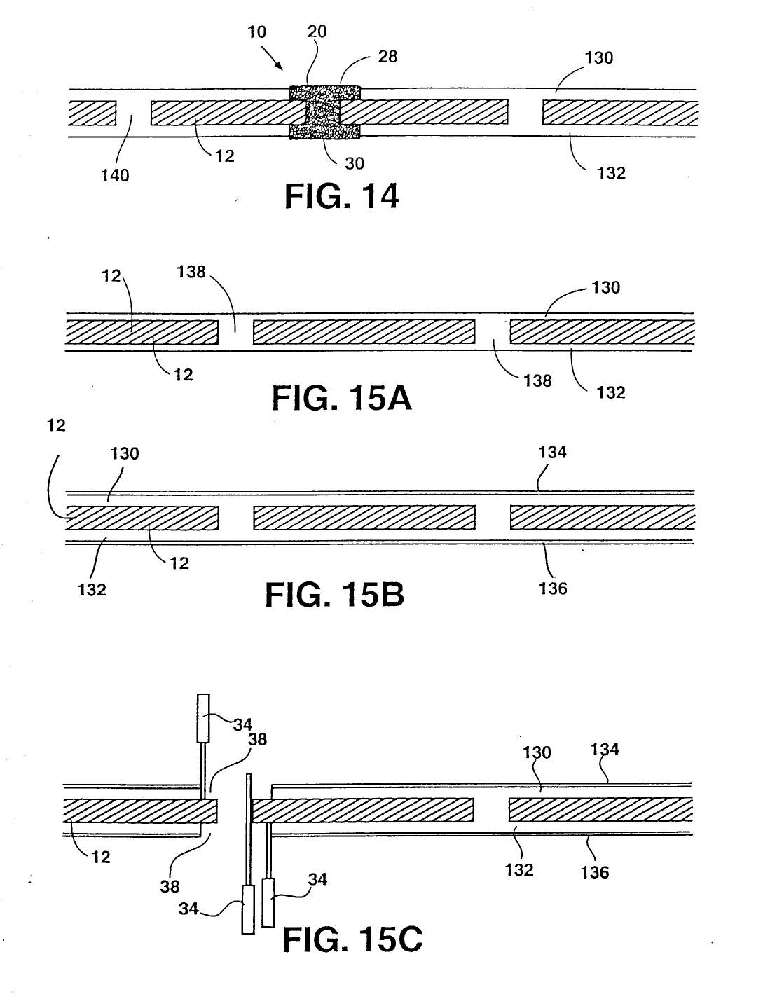

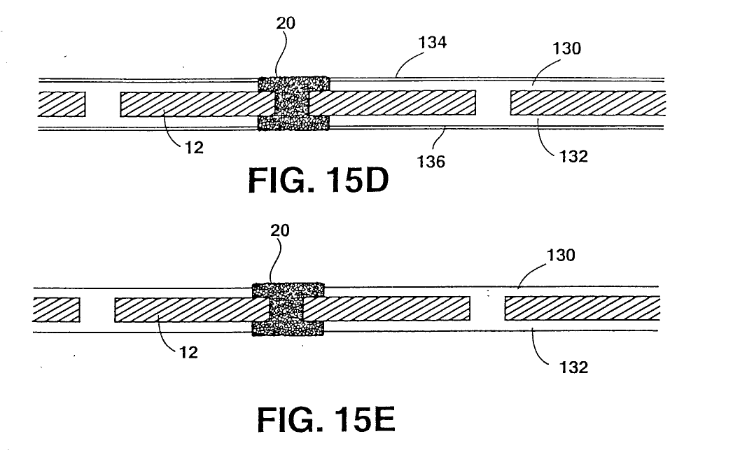

Another preferred embodiment of the interposer of the invention is an interposer shown in FIGS. 14 through 15E. This version of the interposer is similar in shape to the previously described interposer embodiments, but in addition to a layer of insulating material. It also has layers of elastomeric material on one or both sides of the insulating material. The top layer of elastomeric material 130 is less thick than the height of the first conductive region 28, and the bottom layer of elastomeric material 132 is less thick than the second conductive region 30. This results in the first conductive region 28 and the second conductive region 30 protruding slightly beyond the top and bottom elastomeric layers 130 and 132.

When an electrical component comes in contact with the first conductive region 28 and the second conductive region 30, the conductive pad 20 is compressed. When compression is sufficient that the first conductive region 28 and the second conductive region 30 become level with the top and bottom elastomeric layers 130 and 132, resistance to further compression greatly increases and essentially stops. While under this compression, the top and bottom elastomeric layers 130 and 132 confine the first and second conductive regions 28 and 30 to a fixed location, and prevent them from being laterally displaced.

It has been found that the conductive pad 20 experiences optimal conductivity if it is compressed at least 10% of its height. At 40% compression, the elastomers can shear and fail early, so that is considered a maximum figure for compression. A good range of compression is 10% to 30%, and an optimal range is 10% to 25%. It has been found that the conductive regions should extend beyond the elastomeric layers to a total height of half the compression displacement.

FIGS. 15A-15E show a method of making this embodiment of the interposer. First a layer of Kapton has elastomer vias 138 cut with a laser. Next, a top layer 130 of elastomer and a bottom layer 132 of elastomer is added to the Kapton layer, joined by elastomer connectors 140 that extend through the elastomer vias 138, as shown in FIG. 15A. Other methods of affixing the elastomer layers to the planar insulating layer (Kapton) are also possible. Next, a top 134 and a bottom 136 layer of stencil is added to the top elastomer layer 130 and the bottom elastomer layer 132, as shown in FIG. 15B. Next, a first counter bore 36 and the corresponding second counter bore 38 is removed from the elastomer layers and the stencil layers, and a via for the connecting column 32 of the conductive pad 20 is formed in the insulating layer, as shown in FIG. 15C. Then, elastomeric material with conductive granules is added as shown in FIG. 15D. In the last step, the stencil layers are removed, leaving the first conductive region 28 and the second conductive region 30 extending from the top elastomeric layer 130 and the bottom elastomeric layer 132, as shown in FIG. 15E.

While there is shown and described the present preferred embodiment of the invention, it is to be distinctly understood that this invention is not limited thereto but may be variously embodied to practice within the scope of the following claims.

From the foregoing description, it will be apparent that various changes may be made without departing from the spirit and scope of the invention as defined by the following

We claim:

1. An interposer for use with integrated circuit components, which comprises:
a planar insulating layer which defines at least one via through said insulating layer;
at least one conductive pad, each conductive pad comprising a connecting column with a first end and a second end, a first conductive region attached to said first end of said connecting column, a second conductive region attached to said second end of said connecting column, in which said connecting column of said conductive pad passes through said via, and in which said conductive pad is configured to conduct a current between said first conductive region, through said connecting column, to said second conductive region, in which at least one of said conductive regions of said conductive pad is comprised of an elastomeric material in which are embedded a plurality of conductive metallic granules, so that said elastomeric material conducts electricity, and said at least one of said first or second conductive regions is in the shape of a generally flattened disc with a larger diameter than a cross section of said connecting column.

2. The interposer of claim 1 in which said conductive pads are configurable to a pattern to match a pattern of electrodes on an electrical component, in which said electrodes are less than 1 mm apart.

3. The interposer of claim 1 in which said first conductive region, said second conductive region, and said connecting column of said conductive pad are comprised of said elastomeric material embedded with conductive metallic granules.

4. The interposer of claim 3 in which said conductive metallic granules have a diameter of less than 0.001 inches.

5. The interposer of claim 3 in which said first conductive region and said second conductive region have a larger cross sectional size than a cross section of said connecting column.

6. The interposer of claim 1 in which said elastomeric material is conductive either when compressed and also with no compression.

7. The interposer of claim 1 in which said metallic granules make up approximately 70% to 90% by weight of said first conductive region, said second conductive region, and said connecting column of said conductive pad.

8. The interposer of claim 1 which further includes at least one orienting feature, for positive orientation of said interposer in relation to electrical components.

9. The interposer of claim 8 in which said at least one orienting feature comprises one or more orifices defined by said insulating layer which interfit with protruding posts on an IC tester.

10. An interposer for use with integrated circuit components, which comprises:
a planar insulating layer which defines at least one via through said insulating layer;
at least one conductive pad, each conductive pad comprising a first conductive region, a second conductive region, and a connecting column between said first conductive region and said second conductive region, in which said connecting column of said conductive pad passes through said via, and in which said conductive pad is configured to conduct a current between said first conductive region, through said connecting column, to said second conductive region, and in which said first conductive region, said second conductive region, and said connecting column of said conductive pad are comprised of an elastomeric material in which are embedded a plurality of conductive metallic granules, so that said elastomeric material conducts electricity when compressed, and said first conductive region and said second conductive region have a larger diameter than a cross section of said connecting post.

11. The interposer of claim 10 in which said first conductive region and said second conductive region are dumbbell shaped.

12. A method of making an interposer which comprises the steps of:
providing a planar insulative layer with a first side and a second side;
using a laser to cut at least one via through the insulative layer;
installing a conductive pad in said at least one via, in which said conductive pad is comprised of an elastomeric material impregnated with conductive granules, in which said conductive pad includes a first conductive region, a second conductive region, and a connecting column which connects said first conductive region and said second conductive region, so that said connecting column extends through said at least one via, and said first contact region is located adjacent said first side of said planar insulative layer, and said second contact region is located adjacent said second side of said planar insulative layer.

13. A method of making an interposer which comprises the steps of:
providing a planar sheet of insulating material, with a first side and a second side;
covering said first side of said planar sheet of insulating material with a first stencil layer, and covering said second side of said planar sheet of insulating material with a second stencil layer in which is defined at least one first counter bore on said first side and a corresponding second counter bore on said second side of said insulative material;
creating a via through said insulating material inside said first counter bore and said second counter bore;
filling said first counter bore, said via, and said second counter bore with an elastomeric material containing conductive granules;
removing said stencil material from said first side and said second side of said insulative layer.

14. The method of making an interposer of claim 13, which includes the step of using a laser to remove said stencil from said first side and said second side of said insulative layer.

15. The method of making an interposer of claim 13, which includes the step of using chemical means to remove said stencil from said first side and said second side of said insulative layer.

16. The method of making an interposer of claim 15, which includes the step of dissolving said stencil in water.

17. The method of making an interposer of claim 13, which includes the step of using a stencil material which is comprised of photoresist, and making said first and second counter bores said stencil by selectively removing said photoresist layers from said stencil on said first and second side of said insulating layer.

18. The method of making an interposer of claim 17, which includes the step of removing said stencil material from said first and second counter bores by use of a laser, and drilling said vias using a laser.

19. The method of making an interposer of claim 17, which includes the step of removing said stencil material by use of a chemical solvent.

20. The method of making an interposer of claim 13 which in includes the step of supplying a sheet of plastic placed adjacent to said insulating material to serve as said stencil.

21. The method of making an interposer of claim 13, which further includes the step of applying a stencil material which is a flexible sheet with an adhesive back, with perforations in said sheet, which is configured for removal by peeling.

22. An interposer for use with integrated circuit components, which comprises:
a planar insulating layer which defines at least one via through said insulating layer;
at least one conductive pad, each conductive pad comprising a connecting column with a first end and a second end, a first conductive region attached to said first end of said connecting column, a second conductive region attached to said second end of said connecting column, in which said connecting column of said conductive pad passes through said via, and in which said conductive pad is configured to conduct a current between said first conductive region, through said connecting column, to said second conductive region, in which at least one of said conductive regions of said conductive pad is comprised of an elastomeric material in which are embedded a plurality of conductive metallic granules, so that said elastomeric material conducts electricity, and said at least one of said first or second conductive regions is in the shape of a generally flattened disc with a larger diameter than a cross section of said connecting column;
at least one elastomeric layer attached to said planar insulating layer, with said at least one elastomeric layer defining one or more openings through which said conductive regions protrude, and with said at least one elastomeric layer having a thickness less than the height the conductive region extends from said planar insulating layer.

23. The interposer of claim 22 in which said first conductive region, said second conductive region, and said connecting column of said conductive pad are comprised of said elastomeric material embedded with conductive metallic granules.

24. The interposer of claim 23 in which said conductive metallic granules have a diameter of less than 0.001 inches.

25. The interposer of claim 23 in which said first conductive region and said second conductive region have a larger cross sectional size than a cross section of said connecting column.

26. The interposer of claim 22 in which said metallic granules make up approximately 70% to 90% by weight of said first conductive region, said second conductive region, and said connecting column of said conductive pad.

27. The interposer of claim 23 which includes a first elastomeric layer attached to a side of said planar insulating layer, and a second elastomeric layer attached to an opposite side of said planar insulating layer.

28. The interposer of claim 27 in which said first elastomeric layer is attached to said second elastomeric layer by connecting bars which pass through said planar insulating layer through vias in said planar insulating layer.
